(19) United States
(12) Patent Application Publication
(10) Pub. No.: US 2025/0261467 A1
(43) Pub. Date: Aug. 14, 2025

(54) DUAL DEEP TRENCH ISOLATION STRUCTURE FOR IMAGE SENSOR

(71) Applicant: Taiwan Semiconductor Manufacturing Company, Ltd., Hsinchu (TW)

(72) Inventors: Hsin-Hung Chen, Tainan City (TW); Wen-I Hsu, Tainan City (TW); Chih-Kuan Yu, Nantou County (TW); Feng-Chi Hung, Chu-Bei City (TW); Jen-Cheng Liu, Hsin-Chu City (TW); Dun-Nian Yaung, Taipei City (TW)

(21) Appl. No.: 18/438,538

(22) Filed: Feb. 12, 2024

(51) Int. Cl. H01L 27/146

(52) U.S. Cl. CPC H10F 39/807; H10F 39/011

(57) ABSTRACT

Some embodiments relate to a pixel array, including: a substrate including a first side and a second side opposite the first side; a plurality of photodetectors in the substrate, the plurality of photodetectors symmetrically disposed around a middle axis between the plurality of photodetectors, where the middle axis is perpendicular to the first side and the second side; a first doped region at the middle axis between the plurality of photodetectors and on the first side of the substrate; a frontside deep trench isolation (DTI) structure on the first side of the substrate and extending directly between photodetectors of the plurality of photodetectors; and a backside DTI structure on the second side of the substrate and spacing the frontside DTI structure from the middle axis.

### BACKGROUND

Many modern day electronic devices include image sensors. Image sensors have a photodetector, a transfer gate, and a floating diffusion node. The transfer gate is configured to forma conductive path between the photodetector and the floating diffusion node during operation, resulting in a charge in the photodetector being transferred through the floating node to image processing circuitry. The photodetectors are often spaced from one another by a deep trench isolation (DTI) structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D illustrate a top view, cross-sectional views, and a circuit diagram of some embodiments of a frontside DTI structure and a backside DTI structure isolating photodetectors of a pixel array.

FIGS. 2A, 2B, 2C, and 2D illustrate a top view and cross-sectional views of an alternative embodiment of a frontside DTI structure and a backside DTI structure isolating photodetectors of a pixel array, where the backside DTI structure is spaced from a first doped region.

FIGS. 3A, 3B, 3C, and 3D illustrate top views and cross-sectional views of an alternative embodiment of a frontside DTI structure and a backside DTI structure isolating photodetectors of a pixel array.

FIGS. 4A-17B illustrate a series of cross-sectional views of some embodiments of a method of forming a frontside DTI structure and a backside DTI structure isolating photodetectors of a pixel array.

FIG. 18 illustrates a flowchart of some embodiments of a method of forming a frontside DTI structure and a backside DTI structure isolating photodetectors of a pixel array.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A DTI structure comprises an insulative film and a fill layer. The DTI structure extends between and isolates different semiconductor devices or components in a substrate from one another, mitigating the amount of interference that may develop between the semiconductor devices. In a pixel array, some embodiments use a DTI structure to surround and isolate pixels of the pixel array, such that separate photodetectors, floating diffusion nodes, and body contacts are present within the pixels of the pixel array. Forming the DTI structure comprises a high temperature process, resulting in the repair of defects caused by etching the substrate.

As digital technologies advance, more complex integrated devices are called for, and demand has grown for higher resolution pixel arrays that utilize less space. To reduce the footprint (e.g., the space a component uses on a semiconductor device) of each pixel, some embodiments have the floating diffusion nodes and the body contacts shared between multiple pixels in the pixel array. The floating diffusion nodes and the body contacts, in order to reach multiple pixels in the pixel array, are formed at junctions between multiple pixels, taking the place of the DTI structure at those intersections. While this reduces the footprint of the pixel array, this change removes a portion of the DTI structure that isolates the pixels. Lowering the isolation between the pixels reintroduces the potential for interference between the pixels in the pixel array.

Further, the thermal budget available to form variations of the DTI structure is limited by the active components and doped regions of the integrated device. If a DTI structure is formed after the doped regions, the high temperature process to repair defects in the substrate made during the formation would not be within the thermal budget. The introduction of defects in the substrate increases the dark current and potential for leakage current in the integrated device, reducing the performance of the pixel array. Therefore, a device that maintains the reduced footprint offered by the shared floating diffusion nodes, isolates the pixels that share the floating diffusion nodes, and further mitigates the defects in the substrate that result from forming the DTI structure is desirable.

The present disclosure provides for pixel array comprising a frontside DTI structure and a backside DTI structure (or “dual” DTI structure) surrounding the pixels of the pixel array. The frontside DTI structure extends fully through the substrate, extending around a majority of the perimeter of the pixels. The backside DTI structure extends partially through the substrate directly beneath the floating diffusion regions and the body contact regions, further isolating the pixels while not interfering with the functionality of the pixel components. Additionally, the frontside DTI structure is formed before the body contact regions, the floating diffusion nodes, and the photodetectors, and utilizes a high temperature process to repair substrate defects surrounding the frontside DTI structure. The backside DTI structure is formed after the body contact regions, the floating diffusion nodes, and the photodetectors, and has a lower thermal budget. Limiting the backside DTI structure to the regions beneath the floating diffusion regions and the body contact regions mitigates the damage to the substrate caused by the formation of the backside DTI structure.

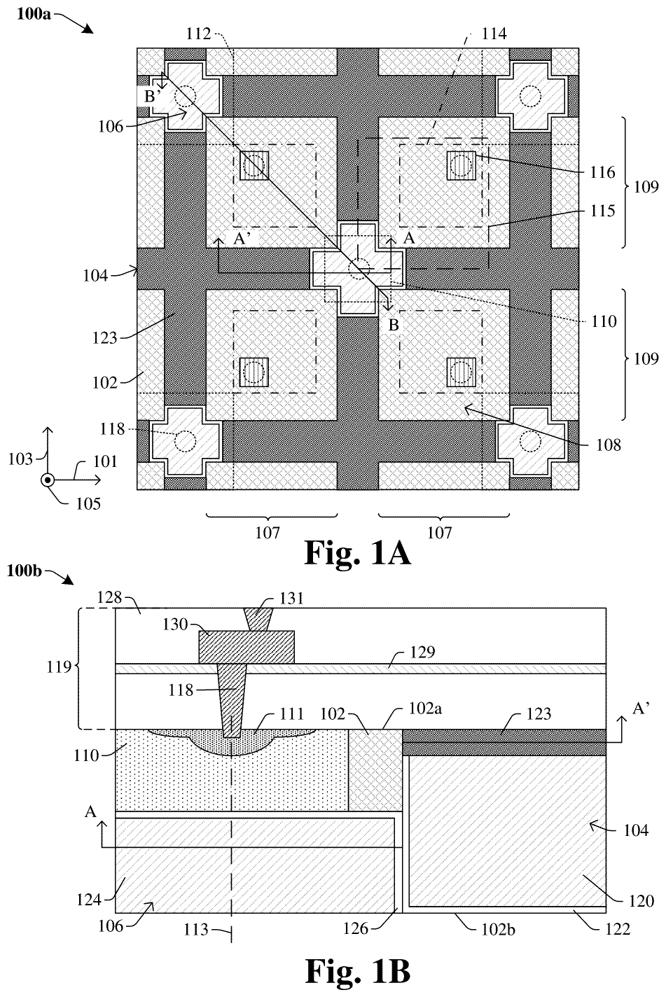

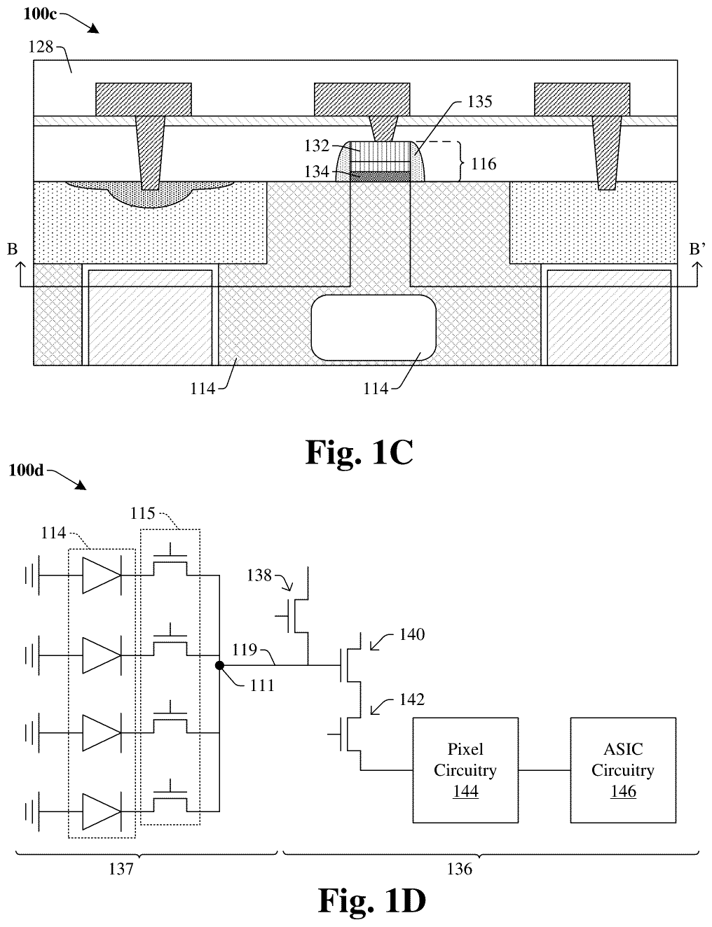

FIGS. 1A, 1B, 1C, and 1D illustrate a top view 100a, cross-sectional views 100b, 100c, and a circuit diagram of some embodiments of a frontside DTI structure and a backside DTI structure isolating photodetectors of a pixel array. The cross-sectional view 100b of FIG. 1B is a view along the line A-A′ of FIG. 1A. The cross-sectional view 100c of FIG. 1C is a view along the line B-B′ of FIG. 1A.

As shown in the top view 100a of FIG. 1A, a frontside DTI structure 104 and a backside DTI structure 106 are disposed within a substrate 102. The frontside DTI structure 104 and the backside DTI structure 106 form continuous loops surrounding pixel regions 108 within the substrate 102. The pixel regions 108 respectively comprise a photodetector of a plurality of photodetectors 114 and a gate stack of a plurality of gate stacks 116. The pixel regions 108 are arranged in a plurality of rows 109 extending in a first direction 101 and a plurality of columns 107 extending in a second direction 103 perpendicular to the first direction 101. The frontside DTI structure 104 and the backside DTI structure 106 together are a grid extending between the plurality of rows 109 and the plurality of columns 107. The backside DTI structure 106 is positioned at alternating intersections of the grid, forming a checkered pattern across intersections of the grid.

The photodetector 114 comprises a doped region of a first conductivity type (e.g., a negative doping type) and the surrounding substrate 102. The plurality of gate stacks 116, in conjunction with first doped regions 110 and the photodetectors 114, are configured to act as transfer transistors 115. The transfer transistors 115 control the formation of a channel between the plurality of photodetectors 114 and first doped regions 110. The first doped regions 110 extend into multiple pixel regions 108, and are used by the pixel regions 108 to transfer charge from the plurality of photodetectors 114 within the pixel regions 108 to an interconnect structure (see 119 of FIG. 1B). The first doped regions 110 have a first conductivity type (e.g., a negative conductivity type). Second doped regions 112 extend into multiple pixel regions 108, biasing the substrate 102 within the multiple pixel regions 108. The second doped regions 112 have a second conductivity type (e.g., a positive conductivity type) and are also referred to as body contact regions.

In order to extend into multiple pixel regions 108, the first doped regions 110 and the second doped regions 112 are positioned between the multiple pixel regions 108. The first doped regions 110 and the second doped regions 112 cannot be formed in the frontside DTI structure 104 that surrounds a majority of the perimeters of the pixel regions 108, as the frontside DTI structure 104 has a capping layer 123 that is or comprises an insulative material. The insulative material would hamper the functioning of the first doped region 110 and the second doped region 112. Therefore, the frontside DTI structure 104 does not continuously surround the pixel regions 108. There are gaps in the frontside DTI structure 104 where the first doped regions 110 and the second doped regions 112 are formed. The gaps are at opposing corners of the frontside DTI structure, resulting in the first doped regions 110 and the second doped regions 112 having a maximum distance from one another while still coupling to the pixel regions 108. The backside DTI structure 106 extends directly beneath the first doped regions 110 and the second doped regions 112. The backside DTI structure 106 and the frontside DTI structure 104 form continuous loops surrounding the pixel regions 108 without interfering with the intended functionality of the first doped regions 110 and the second doped regions 112.

In some embodiments, the pixel regions 108 are symmetrically disposed around a middle axis (see 113 of FIG. 1B) extending through a first doped region of the first doped regions 110. Further, the second doped regions 112 are symmetrically disposed around the middle axis (see 113 of FIG. 1B). The middle axis (see 113 of FIG. 1B) extends in a third direction 105 perpendicular to the first direction 101 and the second direction 103, and extends through a midpoint between the pixel regions 108. The backside DTI structure 106 spaced the frontside DTI structure 104 from the middle axis (see 113 of FIG. 1B).

As shown in the cross-sectional view 100b of FIG. 1B, the frontside DTI structure 104 is on a first side 102a of the substrate and comprises a first fill layer 120, a first insulative liner 122, and a capping layer 123. The capping layer 123 and the first insulative liner 122 are or comprise one or more insulative materials, such as silicon dioxide (SiO₂), silicon nitride (Si₃N₄), or the like. The insulative material mitigates the amount of interference the plurality of pixels may have on one another.

The backside DTI structure 106 is on a second side 102b of the substrate 102 comprises a second fill layer 124 and a second insulative liner 126. The second insulative liner 126 contacts the first insulative liner 122 of the frontside DTI structure 104. In some embodiments, the backside DTI structure 106 extends to the first doped regions 110. In other embodiments, the backside DTI structure 106 is spaced from the first doped regions 110 by the substrate 102. Floating diffusion regions 111 are positioned within the first doped regions 110. The floating diffusion regions 111 have a greater conductivity of the first conductivity type than the first doped regions 110. The first doped regions 110 may also be referred to as lightly doped regions. In some embodiments, the floating diffusion regions 111 have a doping concentration greater than 10¹⁸ cm⁻³, while the first doped regions 110 have a doping concentration less than 10¹⁸ cm⁻³. The floating diffusion regions 111 are configured to transfer the charge generated by the plurality of photodetectors 114 to the interconnect structure 119. The middle axis 113 extends through the first doped region 110 and the backside DTI structure 106.

A plurality of contacts 118 couple the first doped regions 110 and the second doped regions (see 112 of FIG. 1A) to the interconnect structure 119. The interconnect structure comprises one or more wire levels 130 and on or more via levels 131 configured to transfer the received charge to an image processing circuit (see FIG. 1D for details). An interlayer dielectric 128 surrounds the interconnect structure 119. In some embodiments, etch stop layers 129 space the one or more wire levels 130 from the one or more active components (e.g., the transfer transistors 115).

As shown in the cross-sectional view 100c of FIG. 1C, the plurality of gate stacks 116 overlie the substrate 102. The plurality of gate stacks 116 comprise a plurality of gate dielectrics 134 and a plurality of gate electrodes 132. In some embodiments, the plurality of gate dielectrics 134 are in a single layer that extends between multiple gate stacks of the plurality of gate stacks 116. In other embodiments, the plurality of gate dielectrics 134 are a plurality of separate dielectric segments that are spaced by sidewall spacers 135 and the interlayer dielectric 128.

As shown in the circuit diagram 100d of FIG. 1D, the interconnect structure 119 couples the floating diffusion regions 111 to an image processing circuit 136. The image processing circuit 136 comprises pixel circuitry 144, an application-specific integrated circuit (ASIC) 146, a first pixel transistor 138, a second pixel transistor 140, and a third pixel transistor 142. In some embodiments, the photodetectors 114, the transfer transistors 115, and the floating diffusion regions 111 are on a first chip 137, and the image processing circuit 136 is on one or more additional chips. The transfer transistors 115 share the floating diffusion region 111. The plurality of photodetectors 114 are selectively coupled to the floating diffusion region 111 by the transfer transistors 115 (e.g., the coupling of a first photodetector to the floating diffusion region is controlled by a first transfer transistor, etc.). The floating diffusion region 111 is coupled to a source/drain region of the first pixel transistor 138 and a gate of the second pixel transistor 140. The second pixel transistor 140 and the third pixel transistor 142 are serially coupled. The pixel circuitry 144 is coupled to a source/drain region of the third pixel transistor 142. The pixel circuitry 144 may, for example, comprise additional transistors, diodes, resistors, capacitors, inductors, or some other suitable circuitry. In some embodiments, the pixel circuitry 144 is coupled to ASIC circuitry 146. The ASIC circuitry 146 may, for example, comprise transistors, diodes, resistors, capacitors, inductors, or some other suitable circuitry.

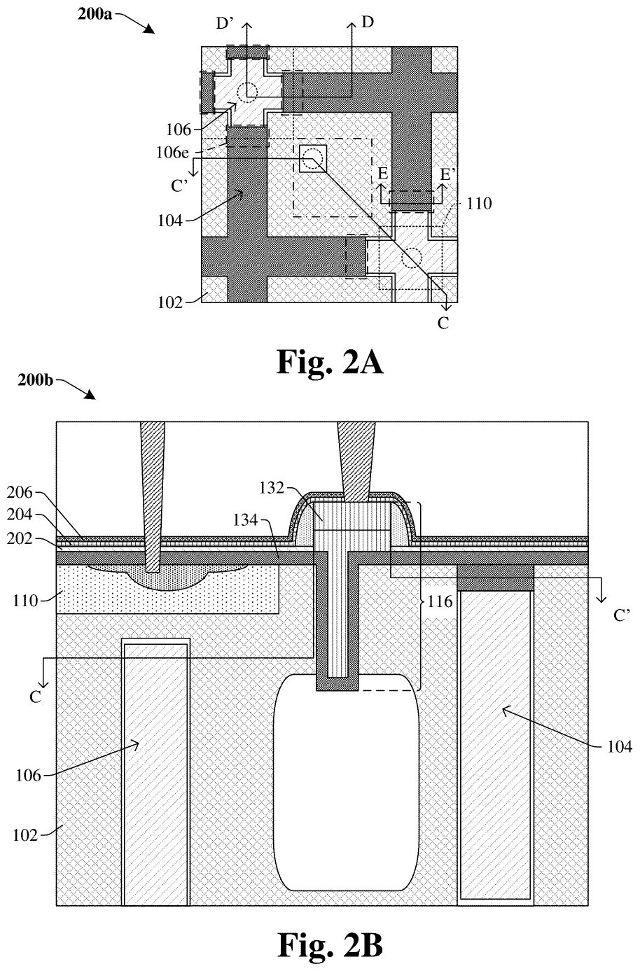

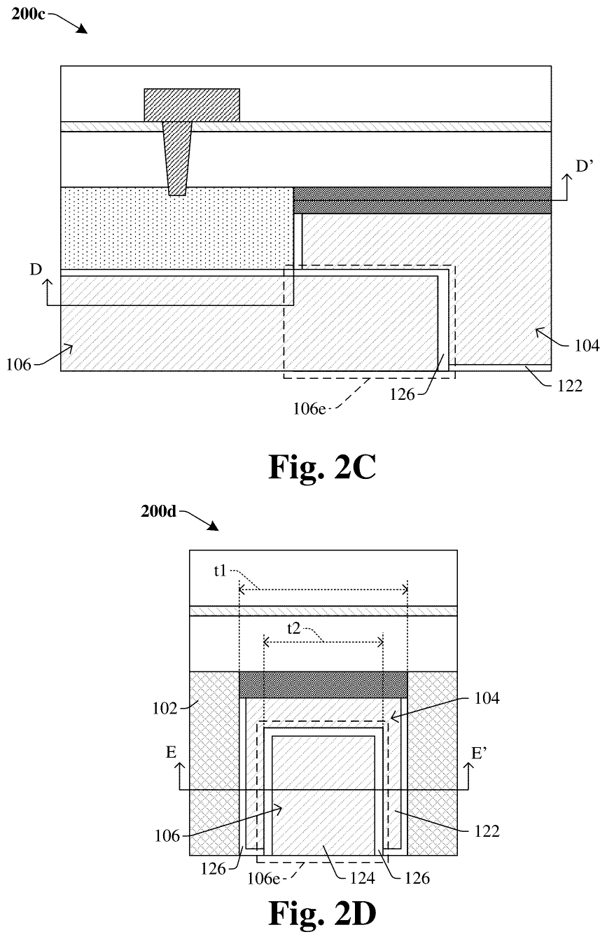

FIGS. 2A, 2B, 2C, and 2D illustrate a top view 200a and cross-sectional views 200b, 200c, 200d of an alternative embodiment of a frontside DTI structure and a backside DTI structure isolating photodetectors of a pixel array, where the backside DTI structure is spaced from a first doped region. The cross-sectional view 200b of FIG. 2B is taken along the line C-C′ of FIG. 2A. The cross-sectional view 200c of FIG. 2C is taken along the line D-D′ of FIG. 2A. FIGS. 2A, 2B, and 2C are described concurrently. The cross-sectional view 200d of FIG. 2D is taken along the line E-E′ of FIG. 2A.

In some embodiments, the backside DTI structure 106 is spaced from the first doped regions 110 by the substrate 102. In some embodiments, the plurality of gate stacks 116 extend into the substrate 102 towards the regions of the plurality of photodetectors 114 with the first conductivity type. In some embodiments, the plurality of gate stacks 116 may further be surrounded by additional layers, such as a high temperature oxide layer 202, a resistive protection layer 204, or a contact etch stop layer 206.

In some embodiments, the backside DTI structure 106 overlaps with the frontside DTI structure 104, replacing portions of the frontside DTI structure 104 with backside DTI structure extensions 106e (see FIGS. 2A and 2C). The backside DTI structure extensions 106e extend into the frontside DTI structure 104 approximately between 20 and 30 nanometers, between 10 and 25 nanometers, between 15 and 30 nanometers, or another, similar range.

As shown in the cross-sectional view 200d of FIG. 2D, in some embodiments, the frontside DTI structure 106 has a first thickness t1 and the backside DTI structure has a second thickness t2, and the second thickness t2 is less than the first thickness t1. The first thickness t1, in some embodiments, is between 160 and 180 nanometers, between 170 and 190 nanometers, between 170 and 180 nanometers, or another, similar range. The second thickness t2, in some embodiments, is between 110 and 130 nanometers, between 120 and 140 nanometers, between 120 and 130 nanometers, or another, similar range. The difference between the first thickness t1 and the second thickness t2 in some embodiments may result in the backside DTI structure extensions 106e being separated from the substrate 102 by the first insulative liner 122 and the second insulative liner 126.

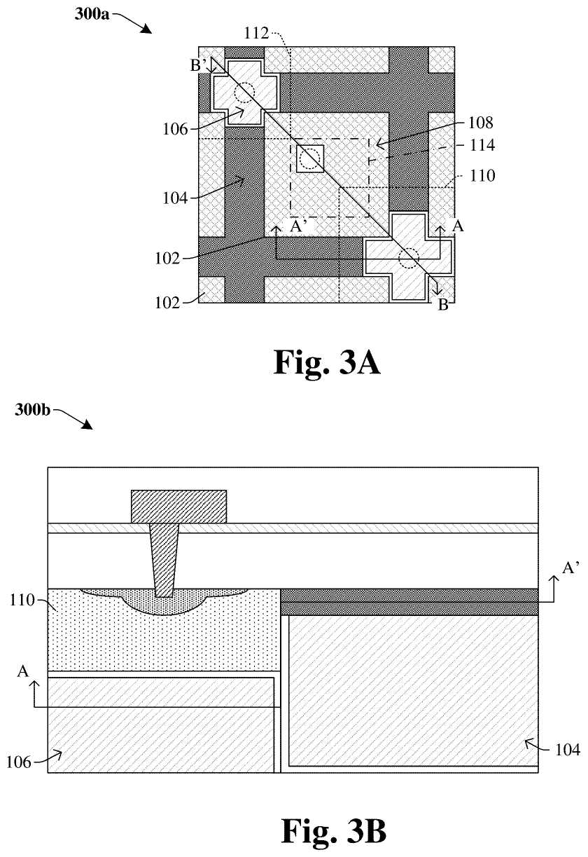

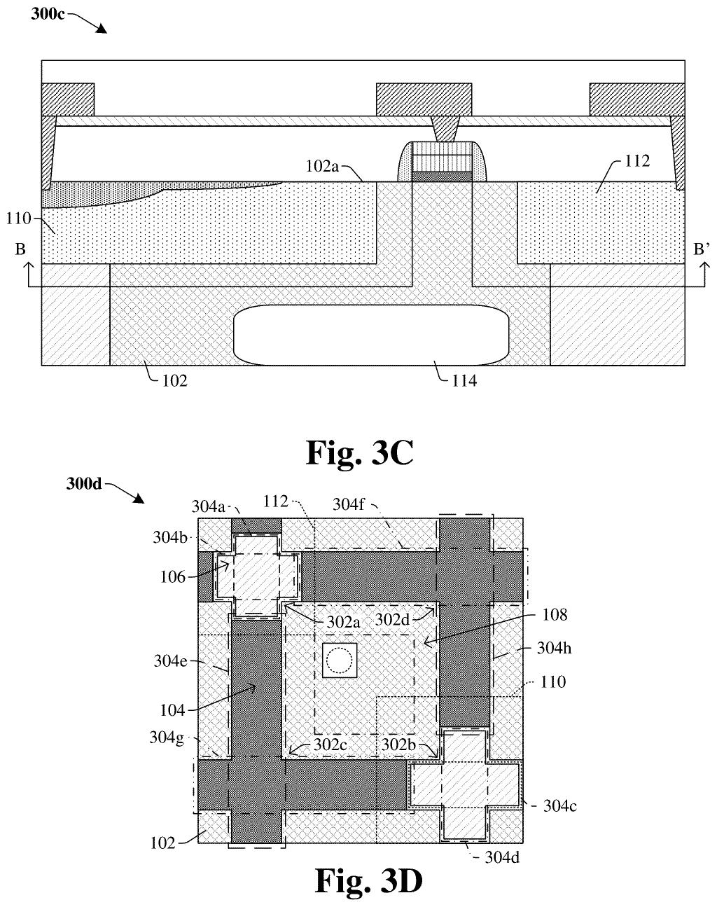

FIGS. 3A, 3B, 3C, and 3D illustrate top views 300a, 300d and cross-sectional views 300b, 300c of an alternative embodiment of a frontside DTI structure and a backside DTI structure isolating photodetectors of a pixel array. The cross-sectional view 300b of FIG. 3B is a view along the line A-A′ of FIG. 3A. The cross-sectional view 300c of FIG. 3C is a view along the line B-B′ of FIG. 3A. The top view 300d shows additional details that are not shown in the top view 300a for clarity.

As shown in the top view 300a of FIG. 3A, in some embodiments the first doped region 110 may extend along sidewalls of the frontside DTI structure 104 past outermost sidewalls of the backside DTI structure 106. The first doped region 110, in some embodiments, directly overlies the photodetectors 114 (shown in phantom). As shown in the cross-sectional view 300b of FIG. 3B, in some embodiments, the first doped region 110 contacts an outer sidewall of the frontside DTI structure 104. In further embodiments, the backside DTI structure 106 also contacts the first doped region 110. As shown in the cross-sectional view 300c of FIG. 3C, in some embodiments, the first doped region 110 overlies the photodetectors 114 and extends across a first side 102a of the substrate 102. In some embodiments, the first doped regions 110 extend over a larger portion of the first side 102a of the substrate 102 than the second doped regions 112.

As shown in the top view 300d of FIG. 3D, in some embodiments, the pixel region 108 comprises a first corner 302a, a second corner 302b, a third corner 302c, and a fourth corner 302d. The first doped region 110 extends over and overlaps with the first corner 302a. The second doped region 112 extends over and overlaps with the second corner 302b. The backside DTI structure 106 comprises a first segment 304a and a second segment 304b that intersect at the first corner 302a. The backside DTI structure 106 further comprises a third segment 304c and a fourth segment 304d that intersect at the second corner 302b. The frontside DTI structure 104 comprises a fifth segment 304e that extends from the first segment 304a, a sixth segment 304f that extends from the second segment 304b, a seventh segments 304g that extends from the third segment 304c, and an eighth segment 304h that extends from a fourth segment 304d of the backside DTI structure 106. The fifth segment 304e and the seventh segment 304g intersect at the third corner 302c of the pixel region 108. The sixth segment 304f and the eighth segment 304h intersect at the fourth corner 302d of the pixel region 108.

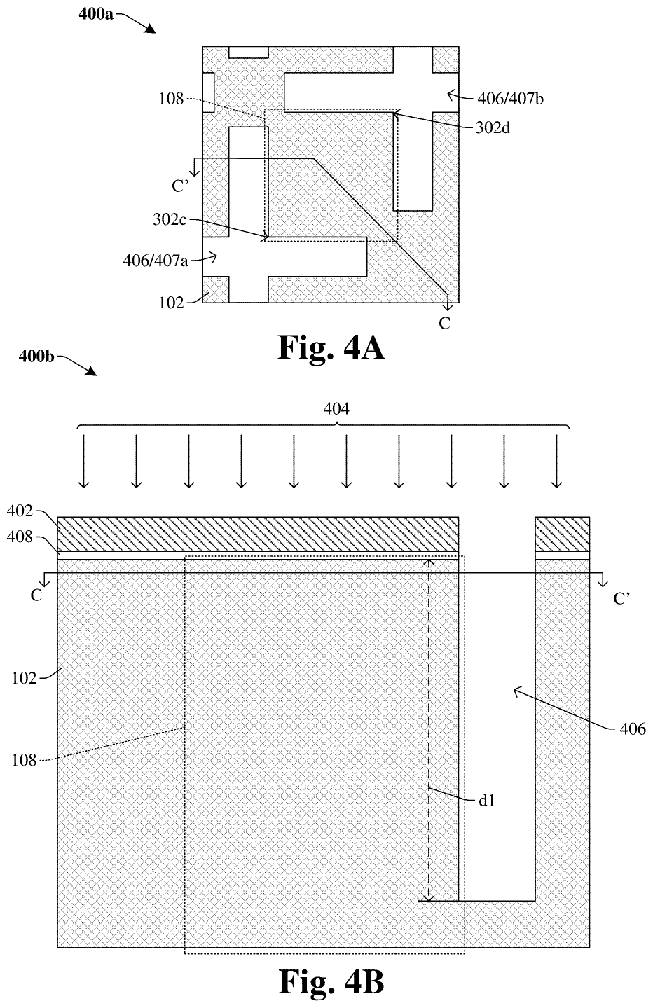

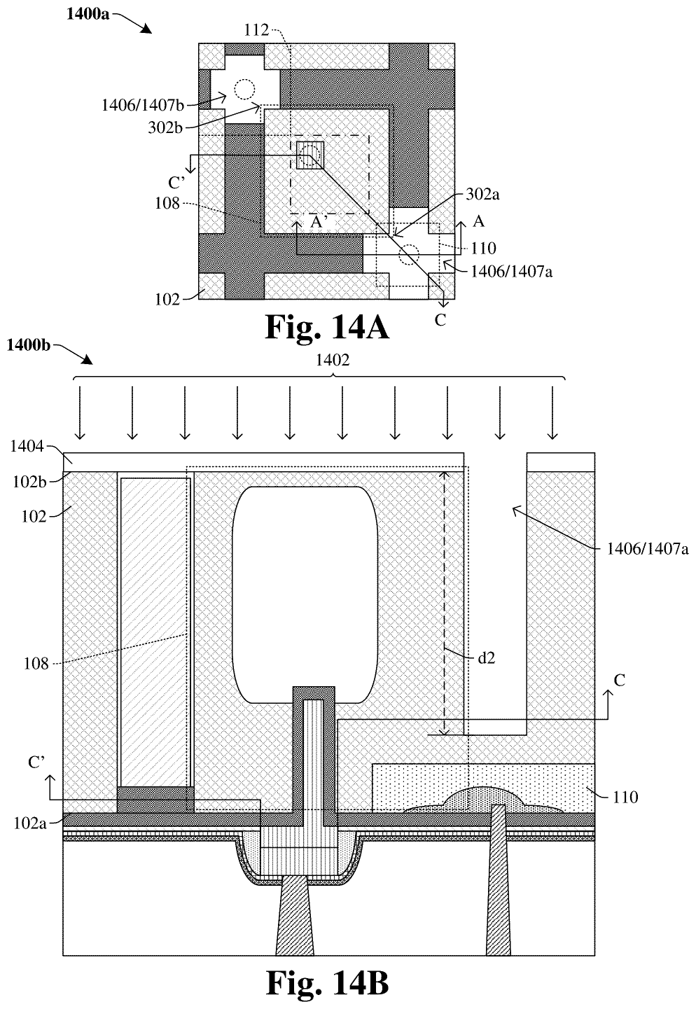

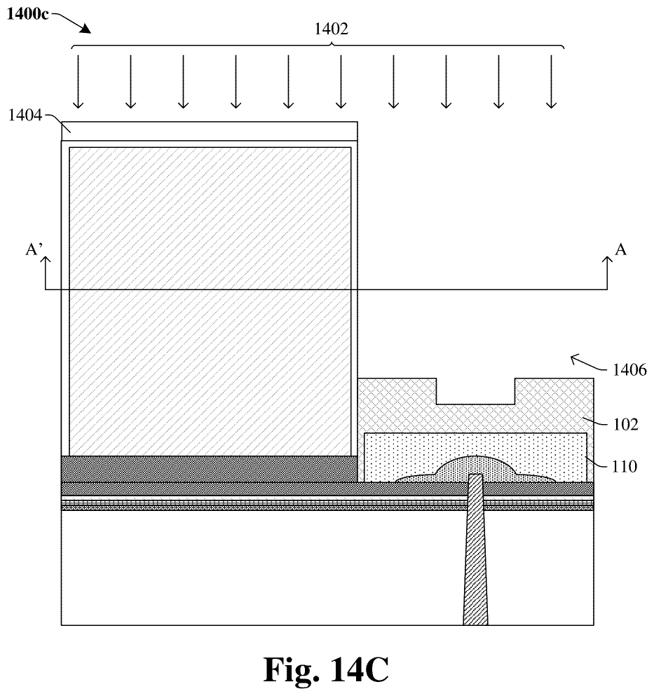

FIGS. 4A, 4B, 5A, 5B, 6A, 6B, 7A, 7B, 8A, 8B, 9A, 9B, 10A, 10B, 11A, 11B, 12A, 12B, 13A, 13B, 14A, 14B, 14C, 15A, 15B, 16A, and 16B illustrate a series of top views and cross-sectional views of some embodiments of a method of forming a frontside DTI structure and a backside DTI structure isolating photodetectors of a pixel array. Of the above listed figures, figures ending with “A” (e.g., FIGS. 4A, 5A, 6A, etc.) are top views, and figures ending with “B” (e.g., FIGS. 4B, 5B, 6B, etc.) are cross-sectional views taken from the line C-C′ of the corresponding top views. FIG. 14C is a cross-sectional view of FIG. 14A taken along the line A-A′ of FIG. 14A. The top views are described concurrently with the corresponding cross-sectional views (e.g., FIG. 4A is described concurrently with FIG. 4B, etc.). Although FIGS. 4A-16B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the top view 400a of FIG. 4A and the cross-sectional view 400b of FIG. 4B, a sacrificial oxide layer 408 and a first masking layer 402 are formed over the substrate 102. The first masking layer 402 may, for example, be formed using chemical vapor deposition (CVD), physical vapor deposition (PVD), atomic layer deposition (ALD), a spin-on process, or the like. The first masking layer 402 is then patterned, revealing portions of the substrate 102 corresponding to the frontside DTI structure (see 104 of FIG. 1A) to be formed hereafter. In some embodiments, the first masking layer 402 is or comprises a photoresist and/or the first masking layer 402 is patterned using photolithography. In other embodiments, the first masking layer 402 is a hard mask comprising silicon nitride (Si₃N₄), silicon dioxide (SiO₂), or the like. The hard mask is patterned utilizing an additional photoresist that is patterned using photolithography and an etching process through the photoresist.

After the first masking layer 402 is patterned, a first etching process 404 is performed on the substrate 102 with the first masking layer 402 in place. The first etching process 404 removes portions of the substrate 102 exposed by the first masking layer 402, forming a first openings 406 within the substrate 102. In some embodiments, the first openings 406 is a series of segments delineating an array within the substrate 102. In some embodiments, the first etching process 404 is a dry etching process. In some embodiments, the first openings 406 have a depth d1 between 2.8 micrometers and 3.2 micrometers, between 2.5 micrometers and 3.1 micrometers, between 2.9 micrometers and 3.5 micrometers, or another, similar range. The first openings 406 comprise a first cross-shaped opening 407a and a second cross-shaped opening 407b. The first cross-shaped opening 407a outlines the third corner 302c of the pixel region 108 and the second cross-shaped opening 407b outlines the fourth corner 302d of the pixel region 108.

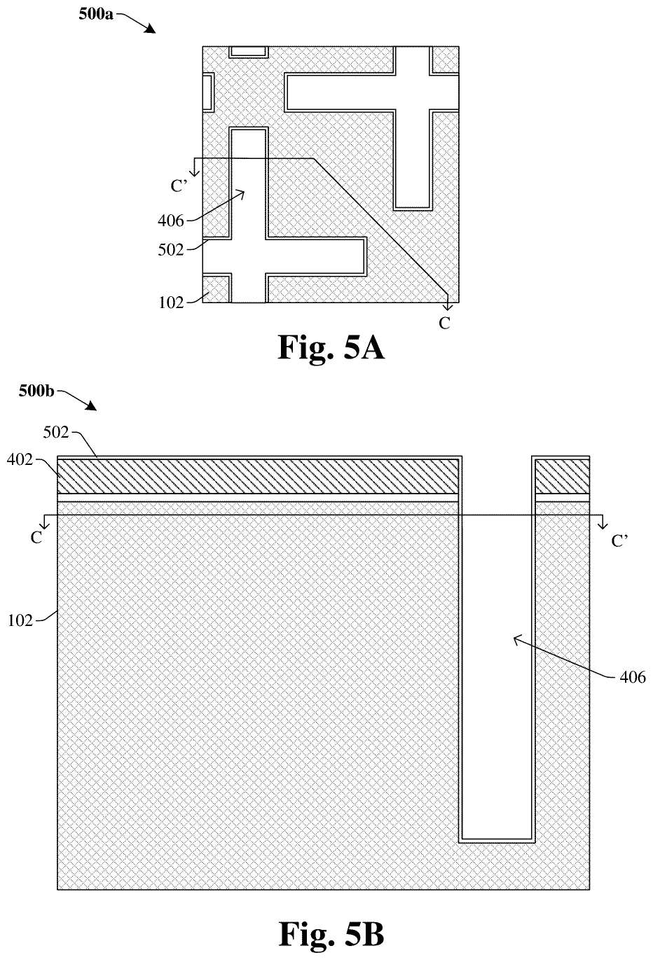

As shown in the top view 500a of FIG. 5A and the cross-sectional view 500b of FIG. 5B, a first conformal liner 502 is formed over the first masking layer 402 and within the first openings 406. In some embodiments, the first conformal liner 502 is formed using CVD, PVD, ALD, or the like. The first conformal liner 502 overlies an upper surface of the first masking layer 402. Further, the first conformal liner 502 covers inner sidewalls and a bottom surface of the first openings 406. In some embodiments, the first conformal liner 502 is or comprises an insulative material, such as silicon dioxide (SiO₂) or the like. The first conformal liner covers inner sidewalls and bottom surfaces of the first openings 406.

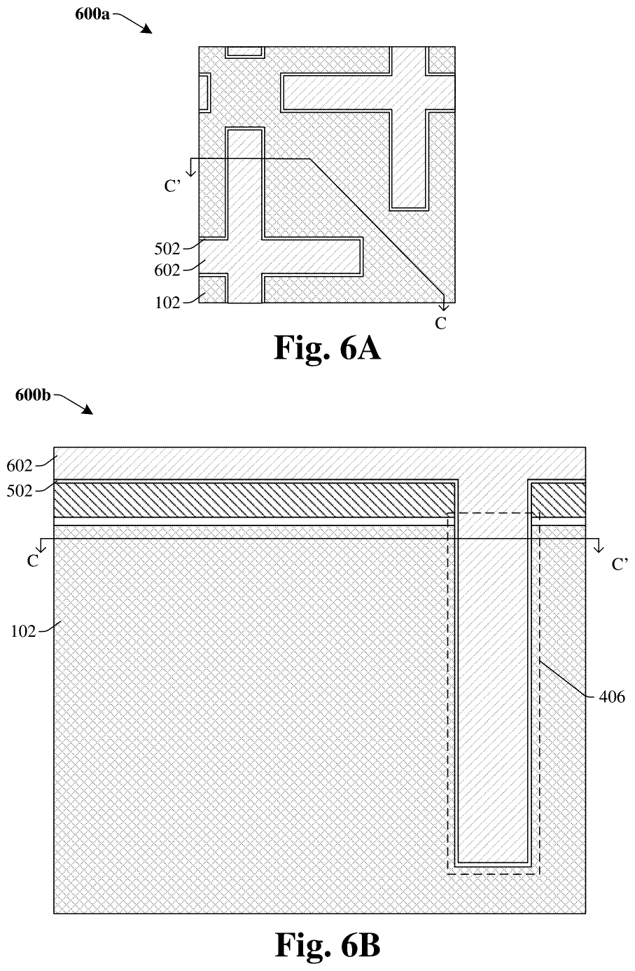

As shown in the top view 600a of FIG. 6A and the cross-sectional view 600b of FIG. 6B, a first conformal fill layer 602 is formed over the first conformal liner 502. In some embodiments, the first conformal fill layer 602 is formed using CVD, PVD, ALD, or the like. The first conformal fill layer 602 overlies an upper surface of the first masking layer 402. Further, the first conformal fill layer 602 covers inner sidewalls and a lower surface of the first conformal liner 502. The first conformal fill layer 602 fills the first openings 406 (shown in phantom). In some embodiments, the first conformal fill layer 602 is or comprises a semiconductor material, such as polysilicon or the like.

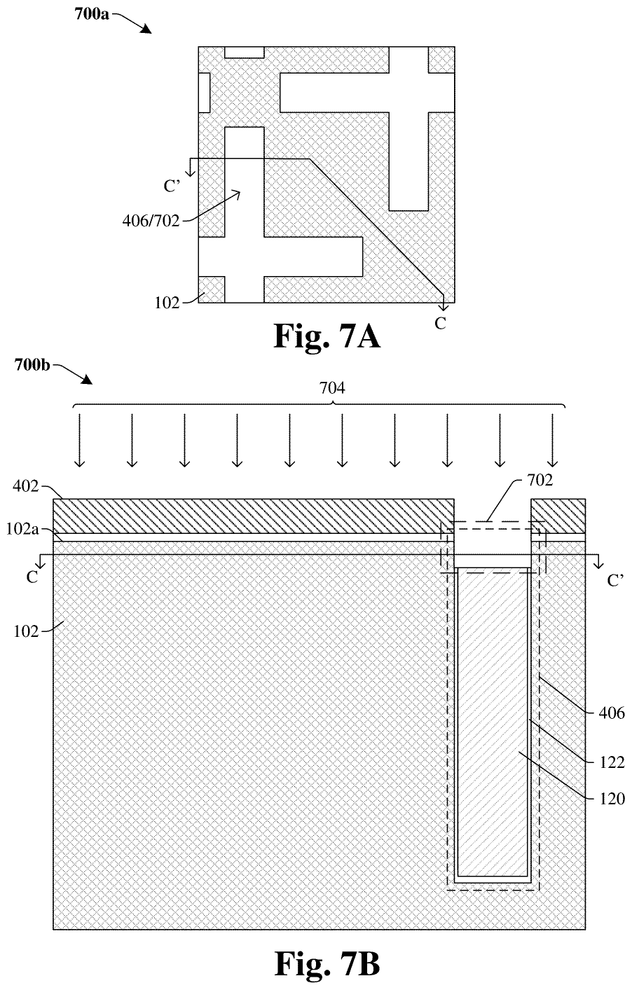

As shown in the top view 700a of FIG. 7A and the cross-sectional view 700b of FIG. 7B, a portion of the first conformal liner (see 502 of FIG. 6) and the first conformal fill layer (see 602 of FIG. 6) extending out of the substrate 102 is removed, leaving the first insulative liner 122 and the first fill layer 120 within the first opening 406. Further, upper portions 702 of the first openings 406 are also exposed, such that the first insulative liner 122 and the first fill layer 120 are recessed from the first side 102a of the substrate 102. In some embodiments, the removal is performed using an etching process 704, removing portions of the first conformal liner (see 502 of FIG. 6) and the first conformal fill layer (see 602 of FIG. 6) above the first masking layer 402 and portions of the first conformal liner (see 502 of FIG. 6) and the first conformal fill layer (see 602 of FIG. 6) exposed by the first masking layer 402.

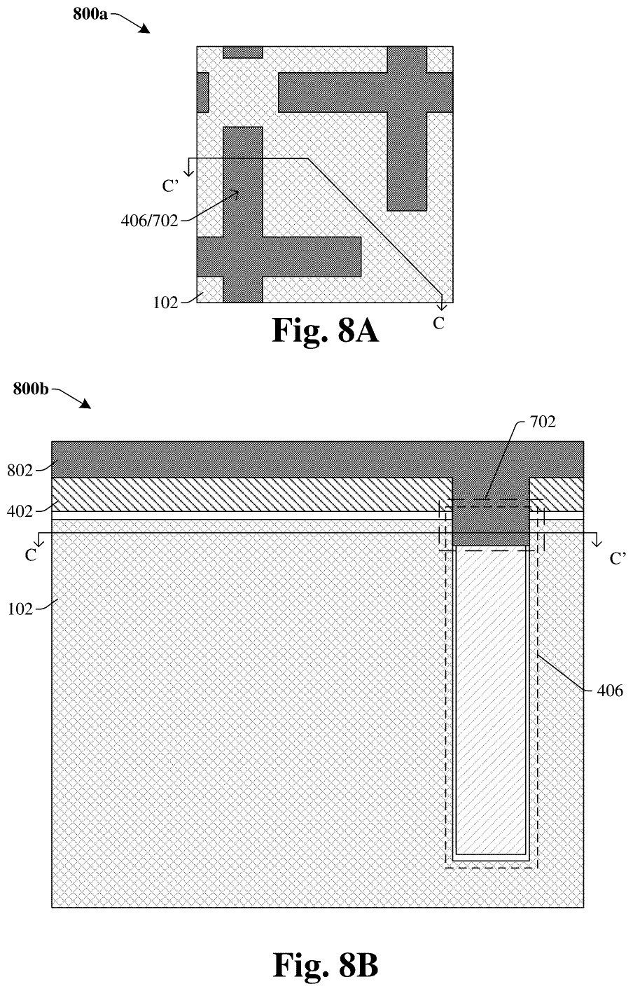

As shown in the top view 800a of FIG. 8A and the cross-sectional view 800b of FIG. 8B, a conformal capping layer 802 is formed within the upper portions 702 (shown in phantom) of the first openings 406 (shown in phantom). In some embodiments, the conformal capping layer 802 is formed using CVD, PVD, ALD, or the like. The conformal capping layer 802 overlies an upper surface of the first masking layer 402. Further, the conformal capping layer 802 covers inner sidewalls of the first openings 406. In some embodiments, the conformal capping layer 802 is or comprises an insulative material, such as silicon dioxide (SiO₂) or the like.

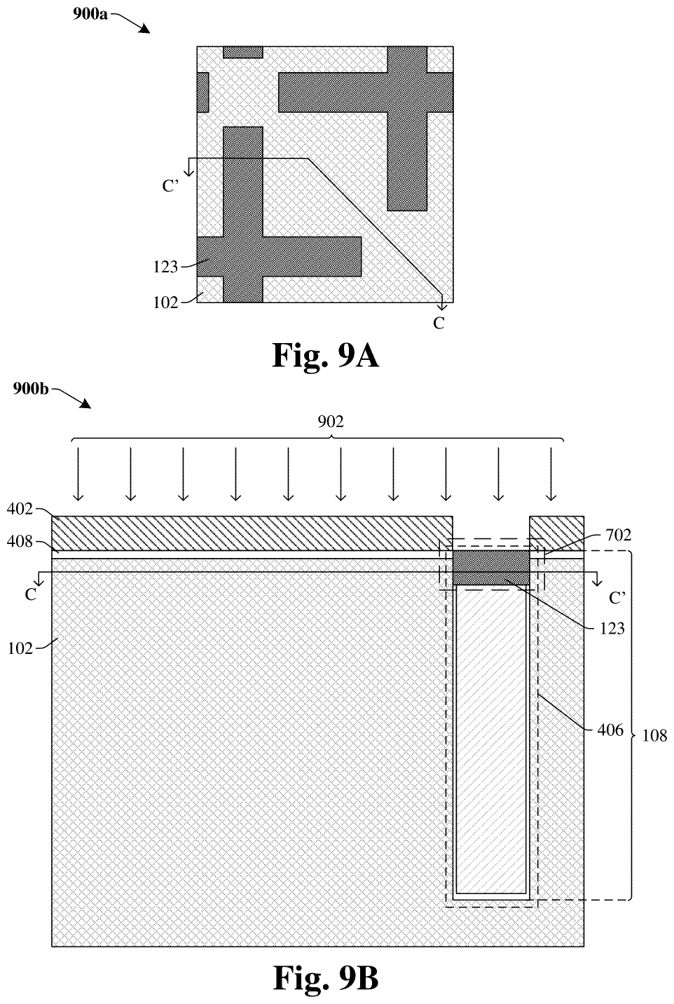

As shown in the top view 900a of FIG. 9A and the cross-sectional view 900b of FIG. 9B, a portion of the conformal capping layer (see 802 of FIG. 8) is removed, leaving the capping layer 123 filling the upper portions 702 (shown in phantom) of the first openings 406 (shown in phantom). In some embodiments, the removal is performed using an etching process 902, removing portions of the conformal capping layer (see 802 of FIG. 8) above the substrate 102. In some embodiments, an upper surface of the capping layer 123 is level with the sacrificial oxide layer 408. In some embodiments, the etching process 902 results in the completion of the frontside DTI structure 104 within the substrate 102. In some embodiments, the formation of the first insulative liner 122, the first fill layer 120, and the capping layer is performed within a temperature range of 900 to 1200 degrees Celsius. In other embodiments, a separate high-temperature (e.g., at 900 to 1200 degrees Celsius) anneal process is performed. The formation of the first insulative liner 122 and the first fill layer 120 before the formation of the first doped regions (see 110 of FIG. 1A) and the second doped regions (see 112 of FIG. 1A) results in a higher thermal budget being available. Resulting from the availability of the higher thermal budget, high temperature processes can be used that repair damage done to the substrate 102 during the etching process described in FIG. 4A. The repairing of the damage done to the substrate 102 increases the passivation of the frontside DTI structure 104, increasing the performance of the integrated device.

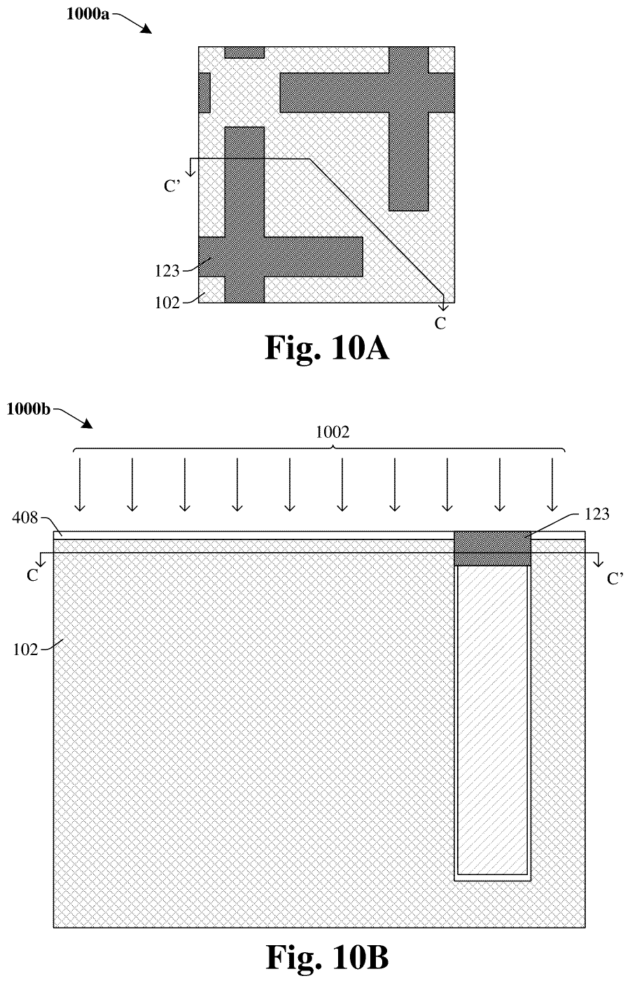

As shown in the top view 1000a of FIG. 10A and the cross-sectional view 1000b of FIG. 10B, a removal process 1002 is performed, removing the first masking layer 402 from the substrate 102. In some embodiments, the removal process 1002 is or comprises a planarization process (e.g., a chemical mechanical planarization (CMP) process), an etching (e.g., a dry etching) process or the like. The removal process 1002 removes the first masking layer 402. In some embodiments, the removal process 1002 further removes the sacrificial oxide layer, exposing the substrate 102.

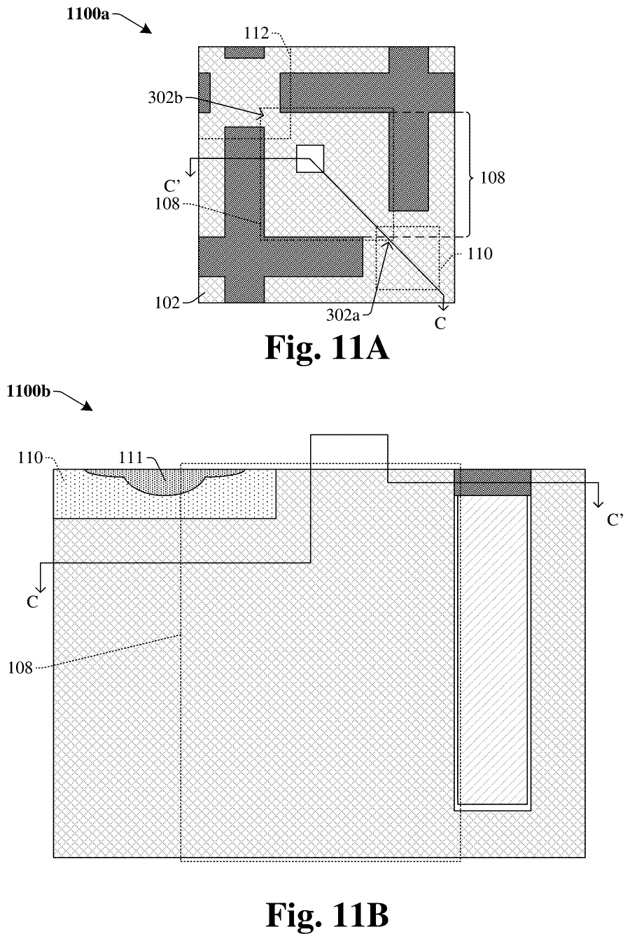

As shown in the top view 1100a of FIG. 11A and the cross-sectional view 1100b of FIG. 11B, the first doped regions 110, the second doped regions 112, and the floating diffusion regions 111 are formed in the substrate 102. The first doped regions 110, the second doped regions 112, and the floating diffusion regions 111 are formed using a doping process. The floating diffusion regions 111 have a greater concentration of dopants than the first doped regions 110.

In some embodiments, the first doped regions 110 and the second doped regions 112 are formed in pattern such that the first doped regions 110 are formed in a first set of rows and columns and the second doped regions are formed in a second set of rows and columns offset from and interleaved with the first set of rows and columns. That is, every row of the first doped regions is spaced from other rows of the first doped regions by rows of the second doped regions. Further, every column of the first doped regions is spaced from other columns of the first doped regions by columns of the second doped regions. This pattern results in individual first doped regions 110 being separated from individual second doped regions 112 by the pixel regions 108, where the photodetectors (see 114 of FIG. 1) will be formed in the following steps. In some embodiments, a first doped regions 110 comprise a first doped region 110 at a first corner 302a of a pixel region 108. The second doped regions 112 comprise a second doped region 112 at a second corner 302b of pixel region 108.

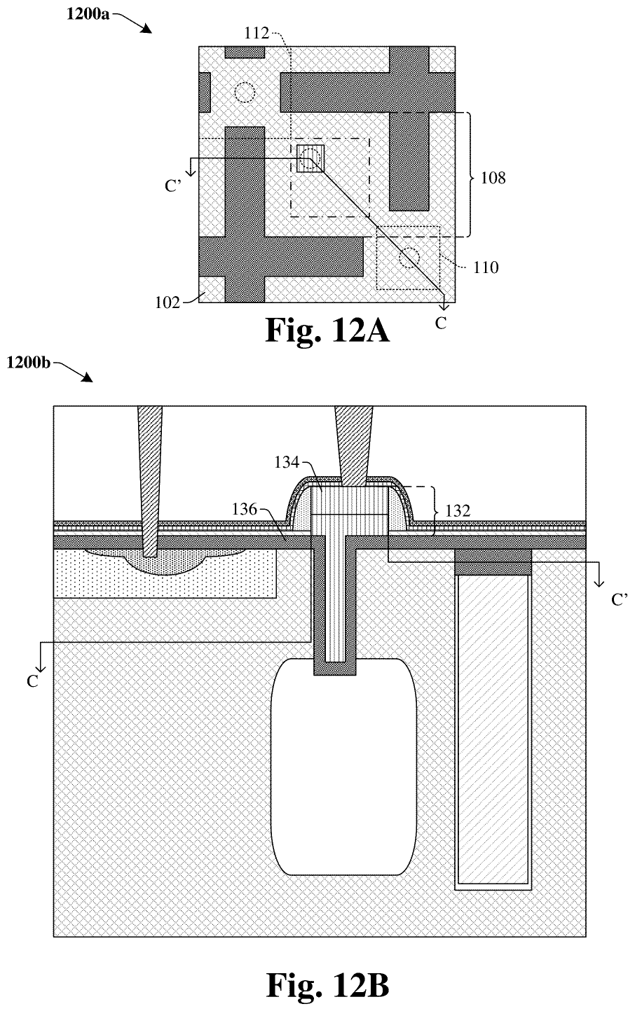

As shown in the top view 1200a of FIG. 12A and the cross-sectional view 1200b of FIG. 12B, the photodetectors 114 and the gate stack 116 are formed on the substrate 102. In some embodiments, the photodetectors 114 are formed using a doping process. In some embodiments, the gate stacks 116 are formed using a plurality of deposition processes, etching processes, or the like to form gate electrodes 132 over the pixel regions 108 and gate dielectrics 134 separating the gate electrodes 132 from the pixel regions 108. In some embodiments, the plurality of gate electrodes 132 extends into the substrate 102. In some embodiments, the high temperature oxide layer 202, the resistive protection layer 204, and the contact etch stop layer 206 may be formed over the gate stacks 116 and the substrate 102.

A plurality of contacts 118 are formed after the formation of the gate stack 116. The plurality of contacts 118 couple the first doped regions 110, the second doped regions 112, and the gate electrodes 132 to an interconnect structure (see 119 of FIG. 1). The interconnect structure has been omitted from FIGS. 12B, 13B, 14B, 15B, and 16B for ease of viewing the top views 1200a, 1300a, 1400a, 1500a, 1600a alongside the corresponding cross-sectional views 1200b, 1300b, 1400b, 1500b, 1600b.

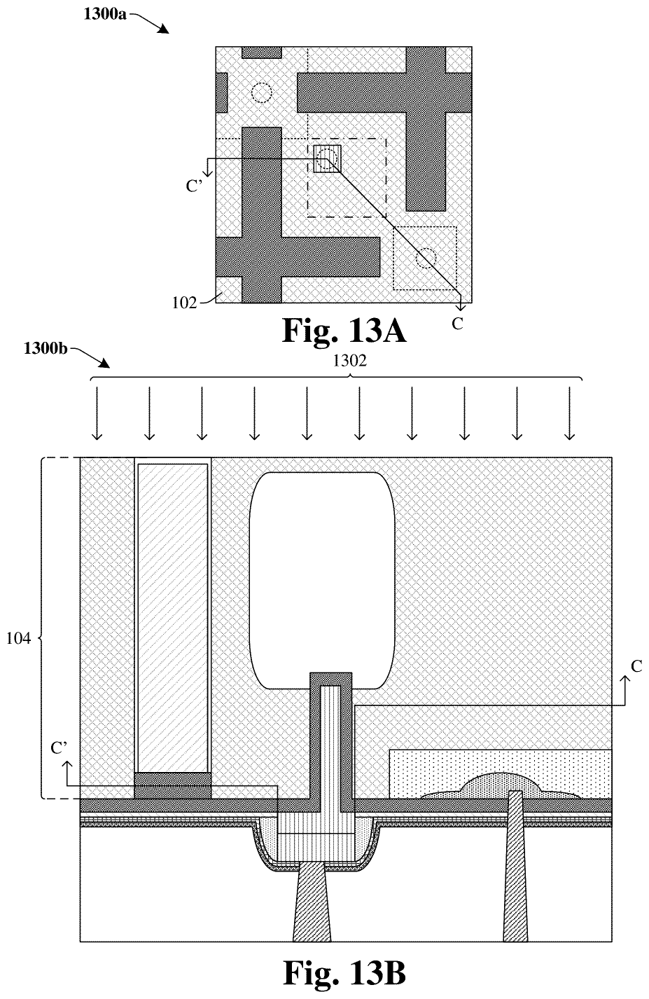

As shown in the top view 1300a of FIG. 13A and the cross-sectional view 1300b of FIG. 13B, a lower portion of the substrate 102 is removed, revealing a lower surface of the frontside DTI structure 104. In some embodiments, the lower portion of the substrate 102 is removed using a planarization process 1302 (e.g., a CMP process) or the like.

As shown in the top view 1400a of FIG. 14A and the cross-sectional view 1400b of FIG. 14B, a second masking layer 1404 is formed over the second side 102b of the substrate 102. The second masking layer 1404 may, for example, be formed using chemical vapor deposition (CVD), physical vapor deposition (PVD), atomic layer deposition (ALD), a spin-on process, or the like. The second masking layer 1404 is then patterned, revealing portions of the substrate 102 corresponding to the backside DTI structure (see 106 of FIG. 1A) to be formed hereafter. In some embodiments, the second masking layer 1404 is or comprises a photoresist and/or the second masking layer 1404 is patterned using photolithography. In other embodiments, the second masking layer 1404 is a hard mask comprising silicon nitride (Si₃N₄), silicon dioxide (SiO₂), or the like. The hard mask is patterned utilizing an additional photoresist that is patterned using photolithography and an etching process through the photoresist.

After the second masking layer 1404 is patterned, a second etching process 1402 is performed on the substrate 102 with the second masking layer 1404 in place. The second etching process 1402 removes portions of the substrate 102 exposed by the second masking layer 1404, forming second openings 1406 within the substrate 102. In some embodiments, the second openings 1406 expose outer sidewalls of the frontside DTI structure 104. The second openings 1406 respectively extend between and space four portions of the frontside DTI structure 104 from one another. The second openings 1406 are vertically aligned with the first doped regions 110 and the second doped regions 112. That is, when the first side 102a of the substrate 102 is above the second side 102b of the substrate 102, the second openings 1406 are directly beneath the first doped regions 110 and the second doped regions 112 (e.g., a portion of the second openings 1406 are directly beneath the first doped regions 110 and a portion of the second openings 1406 are directly beneath the second doped regions 112). In some embodiments, the second openings 1406 extend to the first doped regions 110 and the second doped regions 112. In other embodiments, the second openings 1406 are spaced from the first doped regions 110 and the second doped regions 112. In some embodiments, the second etching process 1402 is a dry etching process. After the second etching process 1402, the second masking layer 1404 is removed. In some embodiments, the second openings 1406 have a depth d2 between 1.8 micrometers and 2.2 micrometers, between 1.5 micrometers and 2.1 micrometers, between 1.9 micrometers and 2.5 micrometers, or another, similar range. In some embodiments, as shown in the cross-sectional view 1400c of FIG. 14C, the second openings 1406 may have a depth that varies along a cross section of the integrated device. The second openings 1406 comprise a third cross-shaped opening 1407a and a fourth cross-shaped opening 1407b. The third cross-shaped opening 1407a outlines the first corner 302a of the pixel region 108 and the fourth cross-shaped opening 1407b outlines the second corner 302b of the pixel region 108.

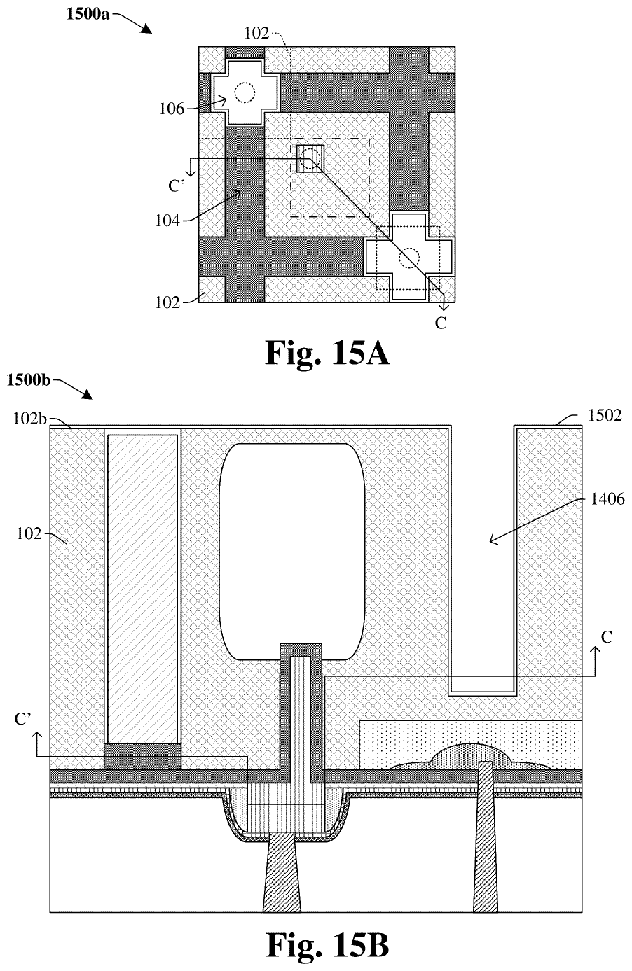

As shown in the top view 1500a of FIG. 15A and the cross-sectional view 1500b of FIG. 15B, a second conformal liner 1502 is formed over the second side 102b of the substrate 102 and within the second openings 1406. In some embodiments, the second conformal liner 1502 is formed using CVD, PVD, ALD, or the like. The second conformal liner 1502 covers inner sidewalls and a bottom surface of the second openings 1406. In some embodiments, the second conformal liner 1502 is or comprises an insulative material, such as silicon dioxide (SiO₂) or the like.

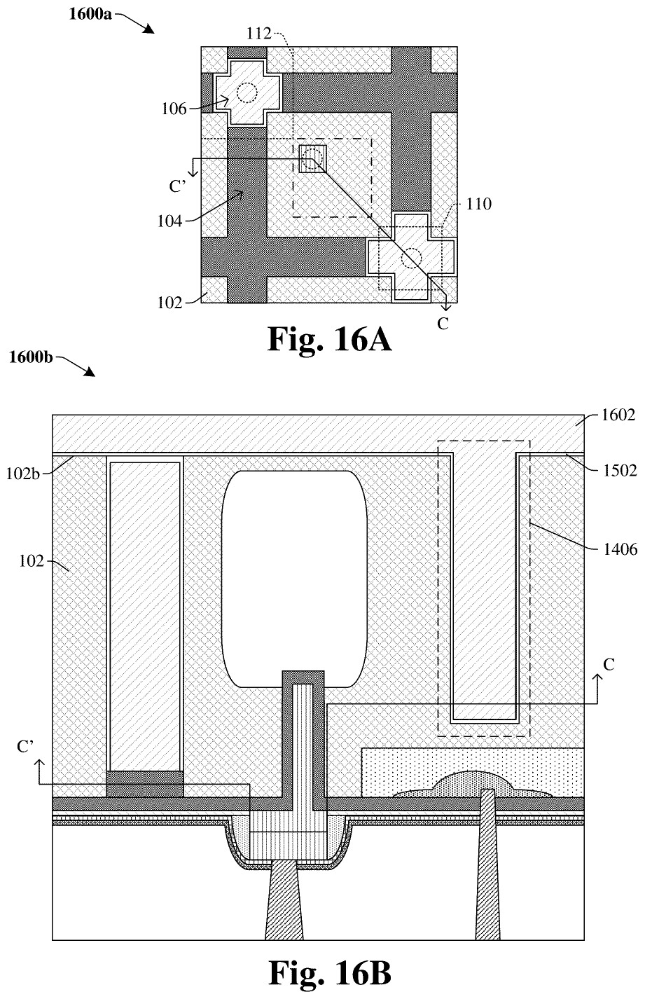

As shown in the top view 1600a of FIG. 16A and the cross-sectional view 1600b of FIG. 16B, a second conformal fill layer 1602 is formed over the second conformal liner 1502. In some embodiments, the second conformal fill layer 1602 is formed using CVD, PVD, ALD, or the like. The second conformal fill layer 1602 covers inner sidewalls and a lower surface of the first conformal liner 502. The second conformal fill layer 1602 fills the first openings 406 (shown in phantom). In some embodiments, the second conformal fill layer 1602 is or comprises a semiconductor material, such as polysilicon or the like. In some embodiments, the formation of the second conformal liner 1502 and the second conformal fill layer 1602 is performed within a temperature range of 300 to 450 degrees Celsius. In other embodiments, a separate low-temperature (e.g., at 300 to 450 degrees Celsius) anneal process is performed. The low temperature range of forming the second conformal liner and the second conformal fill layer is selected to stay within the lower thermal budget available after forming the first and second doped regions 110, 112. The low temperature process reduces the amount the dopants the first and second doped regions 110, 112 diffuse into the substrate 102.

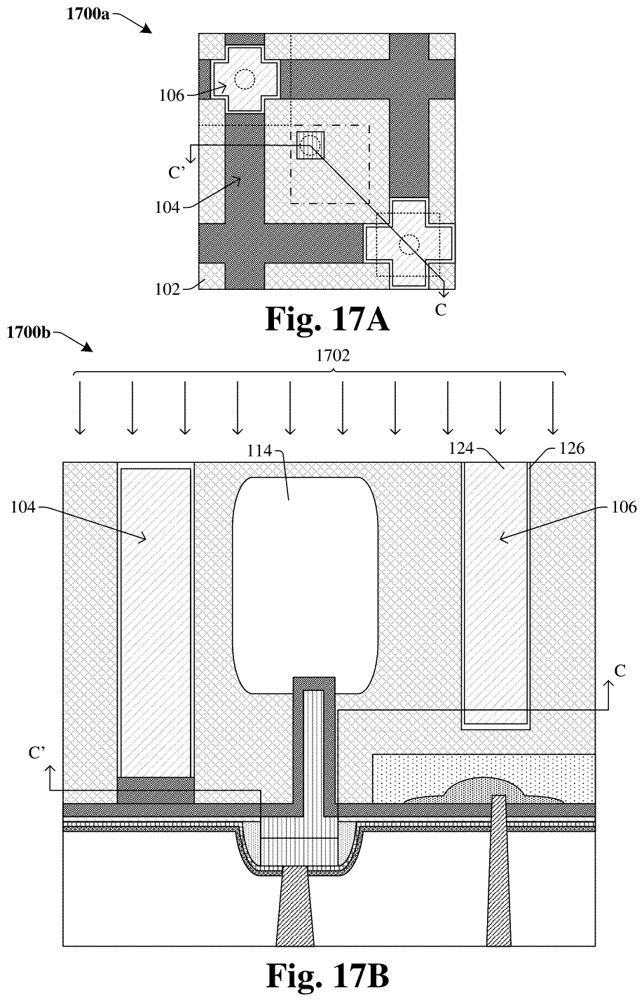

As shown in the top view 1700a of FIG. 17A and the cross-sectional view 1700b of FIG. 17B, after the second conformal fill layer (see 1602 of FIG. 16B) is formed, portions of the second conformal fill layer (see 1602 of FIG. 16B) and the second conformal liner (see 1502 of FIG. 16B) that extend out of the second side 102b of the substrate 102 are removed. In some embodiments, the removal is performed using a planarization process 1702 (e.g., a CMP process). The removal process results in the second fill layer 124 and the second insulative liner 126 remaining within the substrate, forming the backside DTI structure 106.

After the planarization process 1702, the frontside DTI structure 104 and the backside DTI structure 106 combined isolate and form continuous loops around the photodetectors 114 in the pixel regions 108. The frontside DTI structure 104 and the backside DTI structure 16 isolate the pixel regions 108 from one another. The frontside DTI structure 104 being formed before the formation of the photodetectors, doped regions, and active components results in a higher thermal budget being available, and a higher temperature process to be used to repair substrate damage cause by etches performed for the frontside DTI structure 104. As the frontside DTI structure 104 provides a majority of the isolation, the higher temperature process repairs damage to the substrate 102 for a majority of the combined structure, and increases the overall passivation of the combined structure.

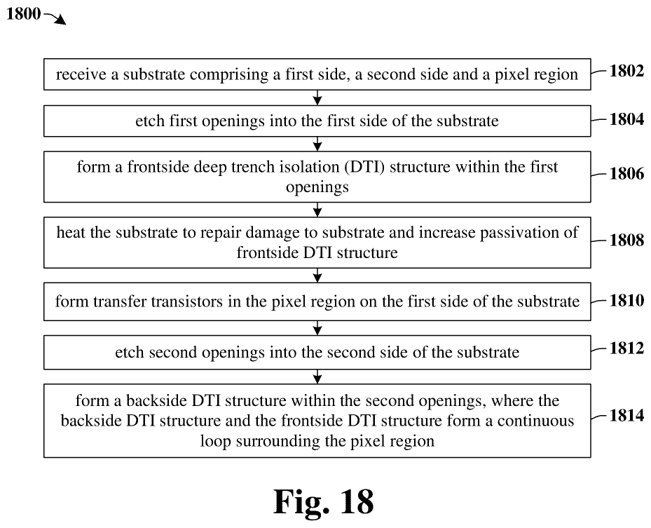

FIG. 18 illustrates a flowchart 1800 of some embodiments of a method of forming a DTI structure with a first film, a second film, and a third film surrounding a DTI core, where the second film is a trapping film. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1802, a substrate comprising a first side, a second side and a pixel region is received. See, for example, in FIG. 4.

At 1804, first openings are etched into the first side of the substrate. See, for example, in FIG. 4.

At 1806, a frontside deep trench isolation (DTI) structure is formed within the first openings. See, for example, in FIGS. 5-10.

At 1808, the substrate is heated to repair damage to the substrate and increase passivation of frontside DTI structure. See, for example, the description of FIG. 7.

At 1810, transfer transistors are formed in the pixel region on the first side of the substrate. See, for example, in FIGS. 11-12.

At 1812, second openings are etched into the second side of the substrate. See, for example, in FIG. 14.

At 1814, a backside DTI structure is formed within the second openings, where the backside DTI structure and the frontside DTI structure form a continuous loop surrounding the pixel region. See, for example, in FIGS. 15-17.

Some embodiments relate to a pixel array, including: a substrate including a first side and a second side opposite the first side; a plurality of photodetectors in the substrate, the plurality of photodetectors symmetrically disposed around a middle axis between the plurality of photodetectors, where the middle axis is perpendicular to the first side and the second side; a first doped region at the middle axis between the plurality of photodetectors and on the first side of the substrate; a frontside deep trench isolation (DTI) structure on the first side of the substrate and extending directly between photodetectors of the plurality of photodetectors; and a backside DTI structure on the second side of the substrate and spacing the frontside DTI structure from the middle axis.

Other embodiments relate to an integrated device, including: a substrate comprising a first side and a second side; a pixel region in the substrate, the pixel region having a first corner, a second corner, a third corner, and a fourth corner when viewed from a top-down perspective; a first photodetector in the pixel region of the substrate; a transistor on the first side of the substrate; a first doped region of a first conductivity type on the first side of the substrate, on a first side of the photodetector, and overlapping the first corner of the pixel region; a second doped region of a second conductivity type on the first side of the substrate, on a second side of the photodetector opposite the first side, and overlapping the second corner of the pixel region opposite the first corner; a backside deep trench isolation (DTI) structure on the second side of the substrate directly beneath the first doped region and the second doped region, the backside DTI structure having a first segment and a second segment that intersect at the first corner of the pixel region and a third segment and a fourth segment that intersect at the second corner of the pixel region; and a frontside DTI structure on the first side of the substrate, the frontside DTI structure having a fifth segment extending from the first segment of the backside DTI structure, a sixth segment extending from the second segment of the backside DTI structure, a seventh segment extending from the third segment of the backside DTI structure, and an eighth segment extending from the fourth segment of the backside DTI structure, where the fifth segment and the seventh segment intersect at the third corner of the pixel region, and the sixth segment and the eighth segment intersect at the fourth corner of the pixel region.

Yet other embodiments relate to a method of forming an integrated device, including: receiving a substrate comprising a first side, a second side and a pixel region, the pixel region having a first corner, a second corner, a third corner, and a fourth corner when viewed from a top-down perspective; etching first openings into the first side of the substrate, the first openings comprising a first cross-shaped opening outlining the third corner of the pixel region and a second cross-shaped opening outlining the fourth corner of the pixel region; forming a frontside deep trench isolation (DTI) structure within the first openings; forming a first doped region of a first conductivity type at the first corner of the pixel region; forming a second doped region of a second conductivity type at the second corner of the pixel region; forming a transfer transistor in the pixel region on the first side of the substrate; etching second openings into the second side of the substrate, the second openings comprising a third cross-shaped opening beneath the first corner of the pixel region and a fourth cross-shaped opening beneath the second corner of the pixel region; and forming a backside DTI structure within the second openings, where the backside DTI structure and the frontside DTI structure form a continuous loop surrounding the pixel region, and the backside DTI structure spaces the frontside DTI structure from the first corner and the second corner of the pixel region.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel array, comprising:
a substrate comprising a first side and a second side opposite the first side;
a plurality of photodetectors in the substrate, the plurality of photodetectors symmetrically disposed around a middle axis between the plurality of photodetectors, where the middle axis is perpendicular to the first side and the second side;
a first doped region at the middle axis between the plurality of photodetectors and on the first side of the substrate;
a frontside deep trench isolation (DTI) structure on the first side of the substrate and extending directly between photodetectors of the plurality of photodetectors; and
a backside DTI structure on the second side of the substrate and spacing the frontside DTI structure from the middle axis.

2. The pixel array of claim 1, wherein:
the frontside DTI structure extends from the first side of the substrate to the second side of the substrate; and
wherein the backside DTI structure extends from a backside of the substrate partially into the substrate, such that the first doped region extends directly between the backside DTI structure and the first side of the substrate.

3. The pixel array of claim 1, wherein the backside DTI structure has a first surface extending between the plurality of photodetectors and the first side of the substrate.

4. The pixel array of claim 1, wherein:
the frontside DTI structure has outer sidewalls that directly contact outer sidewalls of the backside DTI structure.

5. The pixel array of claim 1, wherein:
the frontside DTI structure has a first thickness; and
the backside DTI structure has a second thickness less than the first thickness.

6. The pixel array of claim 1, wherein the backside DTI structure extends into the frontside DTI structure.

7. The pixel array of claim 1, further comprising:
a plurality of second doped regions symmetrically disposed around the middle axis, wherein the plurality of second doped regions have a positive conductivity, and wherein the first doped region has a negative conductivity.

8. The pixel array of claim 7, wherein the frontside DTI structure extends into the plurality of second doped regions.

9. An integrated device, comprising:
a substrate comprising a first side and a second side;
a pixel region in the substrate, the pixel region comprising a first corner, a second corner, a third corner, and a fourth corner when viewed from a top-down perspective;
a first photodetector in the pixel region of the substrate;
a transistor on the first side of the substrate;
a first doped region of a first conductivity type on the first side of the substrate, on a first side of the first photodetector, and overlapping the first corner of the pixel region;
a second doped region of a second conductivity type on the first side of the substrate, on a second side of the first photodetector opposite the first side, and overlapping the second corner of the pixel region opposite the first corner;
a backside deep trench isolation (DTI) structure on the second side of the substrate directly beneath the first doped region and the second doped region, the backside DTI structure comprising a first segment and a second segment that intersect at the first corner of the pixel region and a third segment and a fourth segment that intersect at the second corner of the pixel region; and
a frontside DTI structure on the first side of the substrate, the frontside DTI structure comprising a fifth segment extending from the first segment of the backside DTI structure, a sixth segment extending from the second segment of the backside DTI structure, a seventh segment extending from the third segment of the backside DTI structure, and an eighth segment extending from the fourth segment of the backside DTI structure, wherein the fifth segment and the seventh segment intersect at the third corner of the pixel region, and the sixth segment and the eighth segment intersect at the fourth corner of the pixel region.

10. The integrated device of claim 9, wherein the backside DTI structure extends form the second side of the substrate to the first doped region.

11. The integrated device of claim 9, wherein the first segment and the second segment of the backside DTI structure intersect directly beneath the first doped region;
wherein the third segment and the fourth segment of the backside DTI structure intersect directly beneath the second doped region; and
wherein the first photodetector is directly between the first corner and the second corner of the pixel region.

12. The integrated device of claim 11, wherein the fifth segment and the seventh segment of the frontside DTI structure together extend from the first segment to the third segment of the backside DTI structure and further extend around the third corner of the pixel region; and
wherein the sixth segment and the eighth segment of the frontside DTI structure together extend from the second segment to the fourth segment of the backside DTI structure and further extend around the fourth corner of the pixel region.

13. The integrated device of claim 9, wherein the frontside DTI structure further comprises:
a first fill layer;
a capping layer overlying the first fill layer; and
a first insulative liner surrounding the first fill layer and spacing the first fill layer from the substrate;
and wherein the backside DTI structure further comprises:
a second fill layer; and
a second insulative liner surrounding the second fill layer and spacing the second fill layer from the substrate, wherein the first insulative liner has a first sidewall and the second insulative liner has a second sidewall contacting the first sidewall.

14. A method of forming an integrated device, comprising:
receiving a substrate comprising a first side, a second side and a pixel region, the pixel region having a first corner, a second corner, a third corner, and a fourth corner when viewed from a top-down perspective;
etching first openings into the first side of the substrate, the first openings comprising a first cross-shaped opening outlining the third corner of the pixel region and a second cross-shaped opening outlining the fourth corner of the pixel region;
forming a frontside deep trench isolation (DTI) structure within the first openings;
forming a first doped region of a first conductivity type at the first corner of the pixel region;
forming a second doped region of a second conductivity type at the second corner of the pixel region;
forming a transfer transistor in the pixel region on the first side of the substrate;
etching second openings into the second side of the substrate, the second openings comprising a third cross-shaped opening beneath the first corner of the pixel region and a fourth cross-shaped opening beneath the second corner of the pixel region; and
forming a backside DTI structure within the second openings, where the backside DTI structure and the frontside DTI structure form a continuous loop surrounding the pixel region, and the backside DTI structure spaces the frontside DTI structure from the first corner and the second corner of the pixel region.

15. The method of claim 14, wherein the first doped region extends into the pixel region of the substrate, wherein the second doped region extends into the pixel region of the substrate; and
wherein the backside DTI structure is formed directly beneath the first doped region and the second doped region.

16. The method of claim 15, wherein the frontside DTI structure is formed within a first temperature range, wherein the backside DTI structure is formed within a second temperature range, and wherein a lowest temperature in the first temperature range is greater than a highest temperature in the second temperature range.

17. The method of claim 14, further comprising, after the transfer transistor is formed and before the second openings are etched, performing a planarization process on the second side of the substrate, removing a portion of the substrate beneath a bottom surface of the frontside DTI structure.

18. The method of claim 14, wherein forming the frontside DTI structure further comprises:
forming a first insulative liner over inner sidewalls and bottom surfaces of the first openings;
forming a first fill layer within the first openings, filling the first openings;
removing a portion of the first insulative liner and the first fill layer overlying the substrate and extending into the substrate, exposing upper portions of the first openings; and
filling the upper portions of the first openings with a capping layer.

19. The method of claim 14, wherein forming the backside DTI structure further comprises:
forming a second insulative liner over inner sidewalls and bottom surfaces of the second openings;
forming a second fill layer within the second openings, filling the second openings; and
removing a portion of the second insulative liner and the second fill layer overlying the substrate.

20. The method of claim 14, wherein etching the second openings exposes an outer sidewall of the frontside DTI structure.
